(19) United States
(12) Patent Application Publication
(10) Pub. No.: US 2024/0225122 A1
(43) Pub. Date: Jul. 11, 2024

(54) Aerosol Generation Device Power Monitoring

(71) Applicant: JT International SA, Geneva (CH)

(72) Inventor: Grzegorz Aleksander Pilatowicz, Grens (CH)

(73) Assignee: JT International SA, Geneva (CH)

(21) Appl. No.: 18/573,631

(22) PCT Filed: Jun. 24, 2022
(86) PCT No.: PCT/EP2022/067365

§ 371 Date: Dec. 22, 2023

(30) Foreign Application Priority Data
Jun. 24, 2021 (EP) 21181568.3

(51) Int. Cl. A24F 40/53; A24F 40/20; A24F 40/57; H02J 7/00

(52) U.S. Cl. CPC A24F 40/53; H02J 7/0047; H02J 7/0063; H02J 7/007194; A24F 40/20; A24F 40/57; H02J 2310/22

(57) ABSTRACT

An aerosol generation device is configured to aerosolise an aerosol generating consumable in an aerosolisation session. The aerosol generation device includes a power source and a controller. The controller is configured to control a power flow from the power source to a heater in the aerosolisation session, determine a plurality of power source measurements of the power source as a function of time during the aerosolisation session, and determine whether the power source is capable of powering a subsequent aerosolisation session based upon a determined relationship between the power source measurements as a function of time. The controller is also configured to control the aerosol generation device to perform a further action when it is determined by the controller that the power source is not capable of powering a subsequent aerosolisation session.

### FIELD OF INVENTION

The present invention relates to aerosol generation device, and more particularly power monitoring in aerosol generation devices.

### BACKGROUND

Aerosol generation devices such as electronic cigarettes and other aerosol inhalers or vaporisation devices are becoming increasingly popular consumer products.

Heating devices for vaporisation or aerosolisation are known in the art. Such devices typically include a heating chamber and heater. In operation, an operator inserts the product to be aerosolised or vaporised into the heating chamber. The product is then heated with an electronic heater to vaporise the constituents of the product for the operator to inhale. In some examples, the product is a tobacco product similar to a traditional cigarette. Such devices are sometimes referred to as “heat not burn” devices in that the product is heated to the point of aerosolisation, without being combusted. Other devices are configured to receive a liquid substrate for vaporisation or aerosolisation.

A problem faced by such aerosol generation devices includes providing an accurate monitoring of the charge level of a power source of such devices.

### SUMMARY OF INVENTION

The present invention addresses the aforementioned problem, amongst others.

In a first aspect, there is provided an aerosol generation device configured to aerosolise an aerosol generating consumable in an aerosolisation session, the aerosol generation device comprising: a power source; a controller configured to control a power flow from the power source to a heater in the aerosolisation session, determine a plurality of power source measurements of the power source as a function of time during the aerosolisation session, and determine whether the power source is capable of powering a subsequent aerosolisation session based upon a determined relationship between the power source measurements as a function of time; wherein the controller is configured to control the aerosol generation device to perform a further action when it is determined by the controller that the power source is not capable of powering a subsequent aerosolisation session.

In this way, the charge level of the power source can be accurately monitored and the aerosol generation device can determine whether the power source is capable of powering a full subsequent aerosolisation session based upon measurements taken in the aerosolisation session preceding the subsequent aerosolisation session. When the battery is nearly fully-drained there is a significant risk that after activation of the heater the available energy will be sufficient to start the next session but will not be enough to finish it. This can cause consumer dissatisfaction. Determining whether the power source is capable of powering a full subsequent aerosolisation session based upon measurements taken in the aerosolisation session preceding the subsequent aerosolisation session allows for further action to be taken by the device when the power source is not capable of powering the subsequent aerosolisation session, rather than running out of power during the subsequent aerosolisation session. The user experience can thus be improved. In another advantage, the method does not require adaptation with battery ageing as only the data from last full aerosolisation session is needed to determine if a full subsequent aerosolisation session is possible.

Preferably, determining that the power source is not capable of powering a subsequent aerosolisation session comprises determining that the power source is not capable of powering a full subsequent aerosolisation session.

Preferably, the power source is not capable of powering a subsequent aerosolisation session when the power source does not have enough available energy to power a complete subsequent aerosolisation session.

Preferably, the aerosolisation session comprises a heating phase in which the heater is maintained at the aerosolisation temperature, and the plurality of power source measurements as a function of time comprise a plurality of power source measurements determined in the heating phase.

In this way, the change in voltage of the power source, when a heating load is applied, can be used to accurately determine whether the power source is capable of powering the subsequent aerosolisation session.

Preferably, the controller is configured to determine whether the power source is capable of powering a subsequent aerosolisation session based upon a linear relationship between the power source measurements as a function of time; wherein the power source measurements are voltage measurements of the power source, and the linear relationship is defined as V=at+b, in which V is measured power source voltage as a function of time t in the aerosolisation session, a is change in measured power source voltage per unit time, and b is a voltage offset.

In this way, it can be determined whether the full subsequent aerosolisation session can be performed without using current sensing measurements, thereby reducing costs and complexity. Moreover, computationally intensive mathematical operations are not required, thereby obviating the use of large amounts of memory. This allows for implementation using a low-cost microcontroller.

Preferably, the controller is further configured to determine that the power source is not capable of powering a subsequent aerosolisation session when the change in measured power source voltage per unit time is less than a first threshold and the voltage offset is less than a second threshold.

Preferably, the aerosol generation device further comprises a temperature sensor configured to determine a first temperature of the power source; and wherein the controller is configured to determine the first threshold and the second threshold as a function of the determined first temperature of the power source.

Preferably, the controller is configured to normalise the change in measured power source voltage per unit time and voltage offset to a nominal temperature based upon the determined first temperature of the power source.

Preferably, the controller is configured to: determine a second temperature of the power source after the aerosolisation session; and when the second temperature meets a predetermined temperature requirement, recalculate the normalised change in power source voltage per unit time and the normalised voltage offset based upon the second temperature.

Preferably, the predetermined temperature requirement comprises the second temperature being less than a threshold temperature, and/or a temperature change between the first temperature and a second temperature exceeding a threshold temperature change.

Preferably, the controller is configured to determine that the power source is not capable of powering the subsequent aerosolisation session when the recalculated normalised change in voltage per unit time is less than the first threshold and the recalculated normalised voltage offset is less than the second threshold.

In the time between the aerosolisation session in which the power source voltage measurements have been recorded to determine that a subsequent aerosolisation session can be performed, and the subsequent aerosolisation actually being performed, the aerosol generation device might be exposed to cold conditions that can negatively affect the retentive capacity of the power source. By determining the second temperature after the aerosolisation session, the device can continue to determine whether the power source is capable of powering the next aerosolisation session even after the present aerosolisation session has ended. This allows for further action to be taken by the device when the power source is not capable of powering the subsequent aerosolisation session, rather than running out of power during the subsequent aerosolisation session. In this way, the user experience can thus be improved.

Preferably, the aerosolisation session comprises a preheating phase in which the heater is heated to a predetermined aerosolisation temperature; and wherein the controller is configured to: determine a minimum voltage measurement of the power source in the preheating phase; determine a voltage of the power source at an endpoint of the aerosolisation session based upon the linear relationship; and determine whether the power source is capable of powering a subsequent aerosolisation session based upon a comparison between the determined voltage at the endpoint of the aerosolisation session and the minimum voltage measurement in the preheating phase.

In this way, a further parameter can be used to determine whether the power source is capable of powering the subsequent aerosolisation session, based upon a measurement taken in the preheating phase. This improves the accuracy of the determination, and as such improves the user experience.

Preferably, the further action comprises inhibiting a subsequent aerosolisation session until a predetermined requirement is met.

In this way, the user is inhibited from beginning the subsequent aerosolisation session if the power source is not capable of completing the subsequent aerosolisation session. This improves the user experience as the subsequent aerosolisation session will not cut out partway through.

Preferably, the predetermined requirement comprises charging the power source for a predetermined amount of time.

In this way, the subsequent aerosolisation session can be initiated only when the power source has been adequately recharged to have enough charge stored to be capable of powering the complete subsequent aerosolisation session.

Preferably, the aerosol generation device further comprises an indicator, and the further action comprises indicating, by the indicator, when it is determined by the controller that the power source is not capable of powering a subsequent aerosolisation session.

In this way, the user can be informed that a subsequent aerosolisation session cannot be performed in advance of attempting the subsequent aerosolisation session. That is, an internal state of the device is indicated to the user that can instruct the user to recharge the device, rather than attempt an aerosolisation session that cannot be completed because the power source is not capable of powering the subsequent aerosolisation session. This improves the user experience.

Preferably, the aerosol generating consumable is a tobacco rod, and the aerosol generation device is configured to heat without burning the tobacco rod to produce an aerosol in the aerosolisation session.

In a second aspect, there is provided a method of operating an aerosol generation device configured to aerosolise an aerosol generating consumable in an aerosolisation session, the method comprising: controlling a power flow from a power source to a heater in the aerosolisation session; determining a plurality of power source measurements of the power source as a function of time during the aerosolisation session; determining whether the power source is capable of powering a subsequent aerosolisation session based upon a determined relationship between the power source measurements as a function of time; and performing a further action when it is determined that the power source is not capable of powering a subsequent aerosolisation session.

In a third aspect, there is provided a non-transitory computer-readable medium storing instructions that, when executed by one or more processors of a controller configured for operation with an aerosol generation device configured to aerosolise an aerosol generating consumable in an aerosolisation session, cause the one or more processors to perform steps comprising: controlling a power flow from a power source to a heater in the aerosolisation session; determining a plurality of power source measurements of the power source as a function of time during the aerosolisation session; determining whether the power source is capable of powering a subsequent aerosolisation session based upon a determined relationship between the power source measurements as a function of time; and performing a further action when it is determined that the power source is not capable of powering a subsequent aerosolisation session.

The method of the second aspect and the non-transitory computer-readable medium of the third aspect can be combined with the preferable features of the first aspect, as appropriate.

### BRIEF DESCRIPTION OF THE DRAWINGS

Embodiments of the invention are now described, by way of example, with reference to the drawings, in which:

FIG. 1 is a block diagram of an aerosol generation device;

FIG. 2 is a flow diagram of operating modes of an aerosol generation device;

FIG. 3A is a plot of heater temperature against time for an aerosolisation session;

FIG. 3B is a plot of power delivered to the heater against time for an aerosolisation session;

FIG. 3C is a plot of power source voltage against time for an aerosolisation session for a power source in a strong state and a power source in a weak state;

FIG. 4 is a plot of a pulse width modulated power flow;

FIG. 5 is an exemplary circuit diagram of a power system of an aerosol generation device;

FIG. 6A is a plot of power source voltage against time for a plurality of consecutive aerosolisation sessions;

FIG. 6B-G are enhanced views of power source voltage against time for six of the aerosolisation session of FIG. 6A;

FIG. 7A is an exemplary plot of power source voltage against time for a power source in a strong state and a power source in a weak state;

FIG. 7B is an exemplary plot of linear fits of power source voltage against time measurements recorded during a heating phase for the power source in the strong state and the power source in a weak state of FIG. 7A;

FIG. 8 is process flow diagram of operating steps performed in determining whether a power source is capable of performing a subsequent aerosolisation session;

FIG. 9 presents exemplary plots of retentive capacity versus voltage for a battery at a range of temperatures; and

FIG. 10 presents exemplary plots of power source voltage against time for a plurality of puffs performed on an aerosol or vapour generating device configured to aerosolise of vaporise a liquid-based aerosol or vapour generating material.

### DETAILED DESCRIPTION

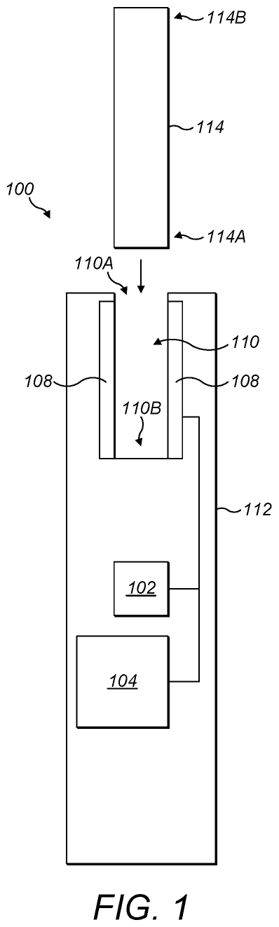

FIG. 1 shows a block diagram of the components of an aerosol generation device 100 or a vapor generation device, also known as an electronic cigarette. For the purposes of the present description, it will be understood that the terms vapor and aerosol are interchangeable.

The aerosol generation device 100 has a body portion 112 containing controller 102, and a power system comprising a power source 104. In an example, the power source 104 is a battery 104. In the following description, the power source 104 is generally referred to as a battery; however, in an alternative, the power source may be a supercapacitor, hybrid capacitor or the like. The power source 104 can be rechargeable. The power system is operable in a plurality of selectable operating modes. The controller 102 is configured to control a power flow of the power source 104 based on the selected operating mode, as will be subsequently described. The controller 102 can be at least one microcontroller unit comprising memory, with instructions stored thereon for operating the aerosol generation device 100 including instructions for executing the selectable operating modes and controlling the power flows, and one or more processors configured to execute the instructions.

In an example, a heater 108 is contained with the body portion 112. In such an example, as shown in FIG. 1, the heater 108 is arranged in a cavity 110 or chamber in the body portion 112. The cavity 110 is accessed by an opening 110A in the body portion 112. The cavity 110 is arranged to receive an associated aerosol generating consumable 114. The aerosol generating consumable can contain an aerosol generating material, such as a tobacco rod containing tobacco. A tobacco rod can be similar to a traditional cigarette. The cavity 110 has cross-section approximately equal to that of the aerosol generating consumable 114, and a depth such that when the associated aerosol generating consumable 114 is inserted into the cavity 110, a first end portion 114A of the aerosol generating consumable 114 reaches a bottom portion 110B of the cavity 110 (that is, an end portion 110B of the cavity 110 distal from the cavity opening 110A), and a second end portion 114B of the aerosol generating consumable 114 distal to the first end portion 114A extends outwardly from the cavity 110. In this way, a consumer can inhale upon the aerosol generating consumable 114 when it is inserted into the aerosol generation device 100. In the example of FIG. 1, the heater 108 is arranged in the cavity 110 such that the aerosol generating consumable 114 engages the heater 108 when inserted into the cavity 110. In the example of FIG. 1, the heater 108 is arranged as a tube in the cavity such that when the first end portion 114A of the aerosol generating consumable is inserted into the cavity the heater 108 substantially or completely surrounds the portion of the aerosol generating consumable 114 within the cavity 110. The heater 108 can be a wire, such as a coiled wire heater, or a ceramic heater, or any other suitable type of heater. The heater 108 can comprise multiple heating elements sequentially arranged along the axial length of the cavity that can be independently activated (i.e. powered up) in a sequential order.

In an alternative embodiment (not shown), the heater can be arranged as an elongate piercing member (such as in the form of needle, rod or blade) within the cavity; in such an embodiment the heater can be arranged to penetrate the aerosol generating consumable and engage the aerosol generating material when the aerosol generating consumable is inserted into the cavity.

In another alternative embodiment (not shown), the heater may be in the form of an induction heater. In such an embodiment, a heating element (i.e., a susceptor) can be provided in the consumable, and the heating element is inductively coupled to the induction element (i.e., induction coil) in the cavity when the consumable is inserted into the cavity. The induction heater then heats the heating element by induction.

It will be understood from the foregoing that the heater 108 can be a heater component such as a heating element or induction coil. Hereinafter, such a heater component is referred to the as a heater, although it will be understood that this term can refer to any of the aforementioned heater components as well as a heater more generally.

The heater 108 is arranged to heat the aerosol generating consumable 114 to a predetermined temperature to produce an aerosol in an aerosolisation session. An aerosolisation session can be considered as when the device is operated to heat the consumable 114 and produce an aerosol from the consumable 114. In an example in which the aerosol generating consumable 114 is a tobacco rod, the aerosol generating consumable 114 comprises tobacco. The heater 108 is arranged to heat the tobacco, without burning the tobacco, to generate an aerosol. That is, the heater 108 heats the tobacco at a predetermined temperature below the combustion point of the tobacco such that a tobacco-based aerosol is generated. The skilled person will readily understand that the aerosol generating consumable 114 does not necessarily need to comprise tobacco, and that any other suitable substance for aerosolisation (or vaporisation), particularly by heating without burning the substance, can be used in place of tobacco.

In an alternative, the aerosol generating consumable can be a vaporisable liquid. The vaporisable liquid can be contained in a cartridge receivable in the aerosol generation device, or can be directly deposited into the aerosol generation device.

The controller 102 is arranged to control the power flow of the energy storage module 104 based upon a selected operating mode of the aerosolisation session. The operating modes can include a preheating mode and a float mode (also referred to as a heating mode).

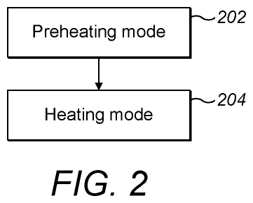

The progression from the preheating mode to the float mode can be understood from FIG. 2.

In the preheating mode 202, the heater 108 associated with the aerosol generation device 100 is heated to a predetermined temperature for the generation of an aerosol from the aerosol generating consumable 114. A preheating phase can be considered the time during which the preheating mode is being executed, for example the time it takes for the heater 108 to reach the predetermined temperature. The preheating mode occurs during a first time period of the aerosolisation session. In an example, the first time period can be a fixed pre-determined time period. In other examples, the first time period can vary corresponding to the length of time needed to heat the heater 108 to the predetermined temperature.

When the preheating phase is complete, the controller 102 ends the preheating mode 202 and controls the power system to perform the float mode 204. In the float mode 204 the controller 102 controls the power flow from the power system to maintain the heater 108 substantially at the predetermined temperature so that an aerosol is generated for the consumer to inhale. A float phase (also referred to as a heating phase) can be considered the time during which the float mode is being executed, for example the time during which the heater 108 is aerosolising one (or at least part of one) aerosol generating consumable 114 after the preheating phase. The controller 102 can control the power system to operate the float mode for a second time period of the aerosolisation session. The second time period can be predetermined and stored at the controller 102.

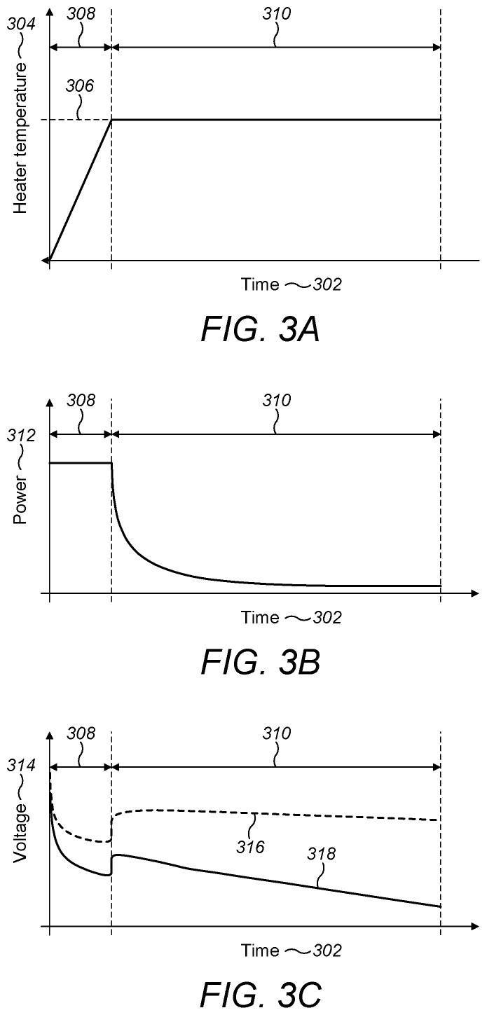

FIGS. 3A, 3B and 3C show exemplary plots of heater temperature 304, average power 312 delivered to the heater 108 and average battery voltage level 314 (respectively) against time 302 for an aerosolisation session. In the preheating phase the controller 102 controls the power system to apply power to the heater 108 for the first time period 308, until the heater temperature reaches the predetermined temperature 306. In an example, the predetermined temperature is 230° C. In an example, the first time period is 20 seconds. In some examples, the controller 102 is configured to heat the heater 108 to the predetermined temperature within a fixed predetermined first time period. In other examples the first time period varies depending on how long the heater 108 takes to reach the predetermined temperature.

When the heater 108 reaches the predetermined temperature 306, the controller 102 switches the operating mode to the float mode (also referred to as the heating mode) for the second time period 310 and maintains the heater temperature substantially at the predetermined temperature 306 for this second time period 310. In an example, the second time period may be 250 seconds.

Typically, a lower power level is applied to the heater 108 in the float mode when maintaining the heater 108 at the predetermined temperature, than the power level applied to the heater 108 to heat it to the predetermined temperature in the preheating mode. This can be seen in FIG. 3B in that the power delivered to the heater 108 in the second time period 310 (float mode) is lower than the power delivered to the heater 108 in the first time period 308 (preheating mode). The power level delivered to the heater 108 can be controlled by various means, for example adjusting the power output from the energy storage module, or by adjusting the on/off periods in a pulse width modulated power flow (as subsequently described).

Following the aerosolisation session the user of the aerosol generation device may be informed that the aerosolisation session has ended, by way of a visual, haptic or audible indicator for example, so that they are aware that the consumable is no longer being aerosolised.

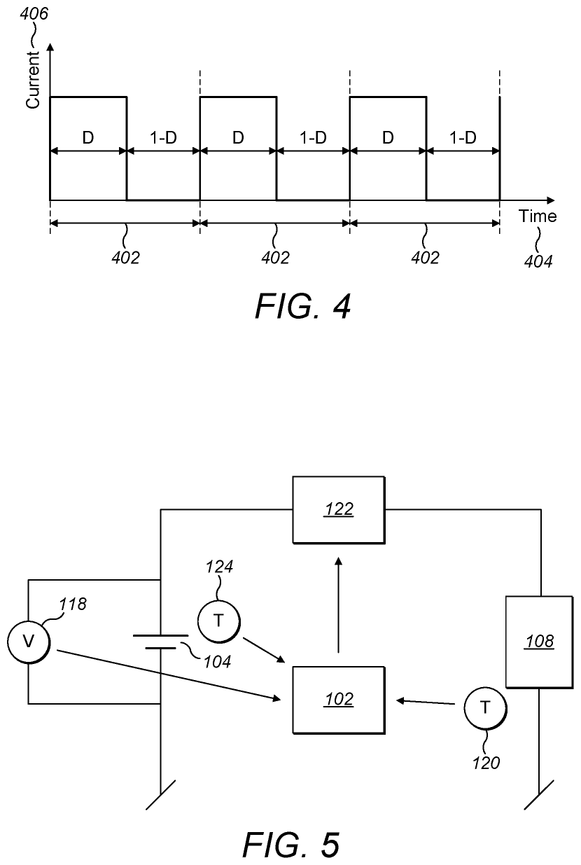

In the preheating and float modes, the controller 102 can control the power flow from the power system to the heater 108 such that the power flow is a pulse width modulated power flow having one or more pulse width modulation cycles. An exemplary pulse width modulated power flow is presented in FIG. 4. A pulse width modulated power flow comprises one or more pulse width modulation (PWM) cycles 402 (also known as pulse width modulation switching periods). A single PWM cycle, or switching period, 402 comprises one PWM cycle “on period” D and one PWM cycle “off period” 1−D. The combination of the PWM cycle on period D and the PWM cycle off period 1−D forms the overall PWM cycle or switching period 402.

During the PWM on period of the PWM cycle, power is applied to the heater 108 by closing a switch that implements the PWM control in a power line to the heater 108. During the PWM off period power is not applied to heater 108 by opening a switch that implements the PWM control in a power line to the heater 108. The switch that implements that PWM control can, for example, be a transistor in a PWM module that is controlled by the controller 102.

One pulse width modulation cycle 402 comprises the power being switched once between an on state and an off state, and a pulse width modulated power flow therefore comprises continuously powering the heater 108 with a power flow which is rapidly switched between PWM on periods and off periods with a duty cycle.

The pulse width modulation duty cycle corresponds to the on period (D) as a proportion of the total period (D+(1−D)) of the cycle 402 (i.e. the combined “on period” and “off period” of the switching period 402).

The pulse width modulated power flow, comprising a plurality of PWM cycles, continuously powers the heater 108 with the average power of the PWM on period and the PWM off period based upon the duty cycle. Controlling the duty cycle controls the amount of power delivered to the heater 108. A higher duty cycle for the pulse width modulated power flow delivers a higher average power; a lower duty cycle for the pulse width modulated power flow delivers a lower average power. That is, for a higher duty cycle a greater proportion of the cycle 402 is the “on period” D than for a lower duty cycle. In this way, careful control of the level of power applied to the heater 108 can be achieved by controlling the duty cycle of the pulse width modulated power flow.

In the float mode, the controller 102 is configured to control the power system to apply the pulse width modulated power flow to the heater 108 with a first duty cycle regime to maintain the heater 108 substantially at the predetermined aerosol generation temperature. In the preheating mode, the controller 102 is configured to control the power system to apply the pulse width modulated power flow to the heater 108 with a second duty cycle regime, different to the first duty cycle regime, to heat the heater 108 to the aerosol generation temperature. The second duty cycle regime can have a higher duty cycle than the first duty cycle regime, in this way a greater amount of power is applied to the heater 108 to rapidly heat it to the predetermined temperature, whilst a lower amount of power is used to maintain the heater 108 at the predetermined temperature. The first duty cycle regime comprises one or more PWM cycles with a first duty cycle ratio D1, and the second duty cycle regime comprises one or more PWM cycles with a second duty cycle ratio D2; the relationship between D1 and D2 can be considered as D2=D1×K, where K is a coefficient that is >>1 and can be selected as an implementation choice; the theoretical maximum duty cycle is 1 with no off period, or close to but less than 1 with a very short off period. In examples, the first duty cycle regime comprises one or more duty cycles with duty cycle ratios much less than 1 and the second duty cycle regime comprises one or more duty cycles with duty cycle ratios near to but less than 1. In other examples, the first duty cycle regime comprises one or more duty cycles with duty cycle ratios<<0.5 and the second duty cycle regime comprises one or more duty cycles with duty cycle ratios≥0.5. In further examples, the first duty cycle is configured such that <3 W is applied in the float mode, and the second duty cycle is configured such that approximately 16 W is applied in the preheating mode. In other examples, the first duty cycle regime can be variable in that the duty cycle is adapted during the float mode in order to maintain the heater 108 at the predetermined temperature; typically, this variable duty cycle in the first duty cycle regime is less than the higher duty cycle used in the second duty cycle regime for the preheating mode.

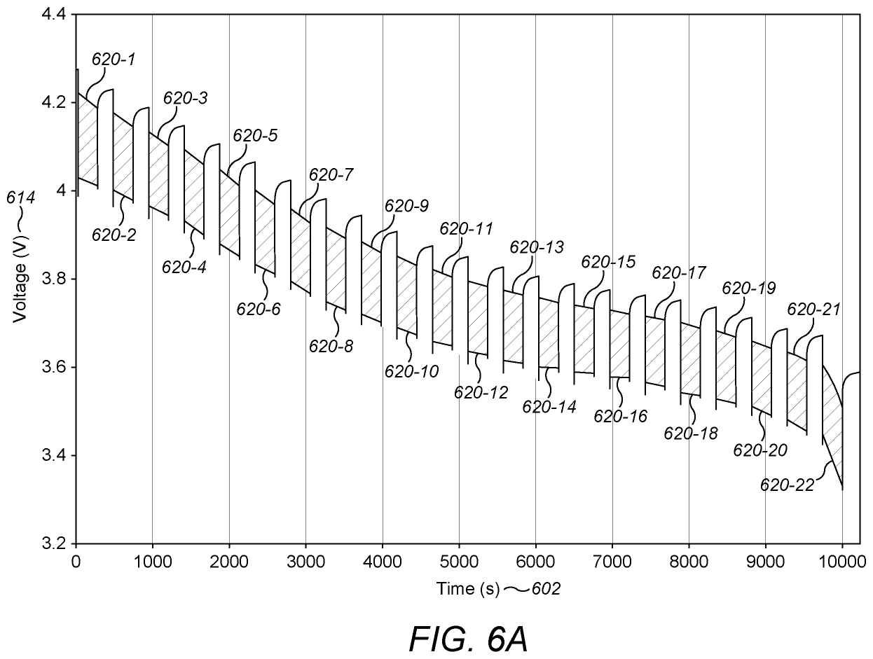

FIG. 5 shows an exemplary circuit diagram of the power system electronics of the aerosol generation device 100. The power system electronics comprise the battery 104, the controller 102, and the heater 108. The power system electronics can further comprise a pulse width modulation (PWM) module 122 that is controlled by the controller 102. The PWM module 122 is configured to apply a pulse width modulation to the power flow from the battery 104 to the heater 108. The controller 102 can control the duty cycle of the pulse width modulation in order to control the power applied to heater 108. For example, when preheating, a high duty cycle can be applied to rapidly heat the heater 108. When the heater 108 is being maintained at the aerosolisation temperature, in the float mode, a lower duty cycle can be applied. The PWM module 122 can comprise a switch, such as a transistor, controlled by the controller 102 to switch between the “on state” and “off state” of each PWM period.

A heater temperature sensor or heater temperature sensing circuit 120 can be arranged at the heater 108 or in the chamber 110 to monitor the heater temperature. The heater temperature is fed back to the controller 102. When the controller 102 determines that the heater temperature has moved above the aerosolisation temperature, the power level applied to the heater 108 can be decreased (for example by reducing the PWM duty cycle). Likewise, when the controller 102 determines that the heater temperature has dropped below the aerosolisation temperature, the power level applied to the heater 108 can be increased (for example by increasing the PWM duty cycle).

A voltage sensor or voltage sensing circuit 118 can be connected to the battery 104, to act as a voltmeter and feedback the battery voltage to the controller 102, so that the controller 102 can monitor the charge status of the battery 104 by determining the voltage level of the battery 104.

A power source temperature sensor 124 or power source temperature sensing circuit can be connected to or near to the battery 104 (or power source, more generally) and can feedback the temperature of the battery 104 to the controller so that the controller can monitor the temperature of the battery 104.

In FIG. 5, the respective connections between the controller 102 and the voltage sensor 118, PWM module 122, power source temperature sensor 124 and heater temperature sensor 120 are represented by arrows for simplicity. However, the skilled person will understand that typical electrical connections between a controller and these components can be used.

Returning to the plot in FIG. 3C, the average battery voltage 314 against time 302 is presented for an exemplary ‘strong’ battery 316 and an exemplary ‘weak’ battery 318. A strong battery can be considered a cell that has plenty of energy available and is capable of powering multiple subsequent aerosolisation sessions. In an example, a strong battery such as a fully charged battery may be able to fully power around 20 aerosolisation sessions. In another example, a strong battery (but not necessarily fully charged) may be able to fully power two or more subsequent aerosolisation sessions. A weak battery can be considered a battery that is not capable of fully powering any subsequent aerosolisation sessions, or very few sessions (for example, one subsequent aerosolisation session), due to battery aging, a low state of charge, or a low operating temperature. As can be seen, the gradient of the battery voltage against time during the float/heating mode is greater for the weak battery 318 than the strong battery 316. That is, the gradient of battery voltage against time is indicative of whether the battery 104 is capable of powering a full subsequent aerosolisation session.

The battery total internal resistance observed in the time domain comprises ohmic internal resistance, passivation films/layers resistance, charger-transfer internal resistance and concentration-related effects such as diffusion, migration and convection. When the battery is ‘strong’ the contribution of the 1st three resistances are more significant. However when the battery is ‘weak’ the contribution of the concentration-related effects become much higher than the others due to ion depletion causing a lower concentration of ions than the equilibrium. The overvoltage/polarization caused by this phenomenon can be described by natural logarithm function In(actual concentration/equilibrium concentration). Therefore, if the actual concentration noticeably drops, the voltage drop/higher resistance can become much higher, as observed for the ‘weak’ battery compared to the ‘strong’ battery in FIG. 3C. As the concentration-related effects typically appear later than the other three effects, the slope is more observable in the heating mode than in the pre-heating mode. For completeness, in the present context, ‘weak’ does not have to necessarily mean nearly fully discharged, it can be also related to ageing or low temperature or a combination thereof.

As can also be seen in FIG. 3C, the voltage offset (the offset on the voltage axis) is greater for the strong battery 316 than for the weak battery 318. That is, the voltage offset of the battery voltage against time is also indicative of whether the battery 104 is capable of powering a full subsequent aerosolisation session.

In the context of the present disclosure, a subsequent aerosolisation session can be considered as the next aerosolisation session, that is yet to occur, after the present aerosolisation session that is being currently being performed, or the next aerosolisation session after the most recent aerosolisation session that has been performed when an aerosolisation session is not presently being performed.

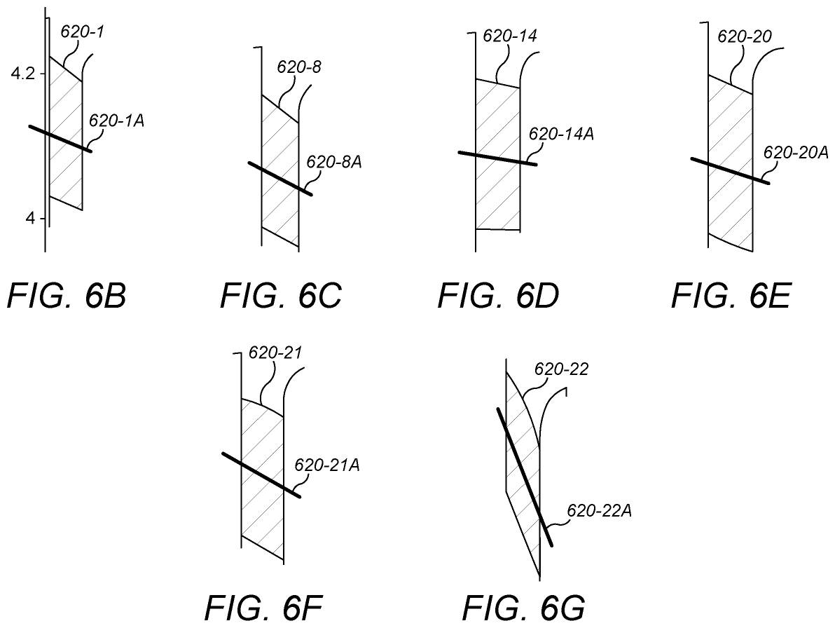

FIG. 6A shows a plot of measured battery voltage 614 against time 602 for 22 consecutive aerosolisation sessions, 620-1 to 620-22, with a brief pause between each session. Each of the blocks 620-1 to 620-22 represents one aerosolisation session. In this example, a pulse width modulated power flow is applied to the heater 108; hence, the line representing the measured battery voltage has a thickness in the blocks 620-1 to 620-22 due to the load rapidly being applied and removed from the battery 104 affecting the measured battery voltage. Between each aerosolisation session, some battery recovery occurs, which causes the increasing voltage between the end of one session and the beginning of the next.

As can be seen, the measured battery voltage follows an overall downward trend as the state-of-charge of the battery 104 drops as the number of aerosolisation sessions executed increases. It can also be seen that for the later sessions (e.g. 620-20 and 620-21), the gradient of the measured battery voltage against time trends more steeply downward between the beginning and end of each aerosolisation session; i.e. the rate at which the measured battery voltage drops increases with time. The measured battery voltage following an overall downward trend is due to the charge level in the battery 104 dropping, and can be used to determine if the battery 104 is capable of powering a full subsequent aerosolisation session.

FIGS. 6B to 6E respectively show enhanced views of aerosolisation sessions 620-1, 620-8, 620-14, 620-20, 620-21 and 620-22.

Aerosolisation sessions 620-1, 620-8, 620-14 and 620-20 all correspond to a ‘strong’ battery 104, whereas aerosolisation sessions 620-21 and 620-22 correspond to a ‘weak’ battery 104. In this example, the battery 104 has become weaker in that the state-of-charge has dropped due to the number of aerosolisation sessions that have been performed without recharging in-between.

Exemplary fitting lines 620-1, 620-8, 620-14, 620-20, 620-21 and 620-22 (change of voltage with respect to time) are presented respectively overlaying the enhanced views of aerosolisation sessions 620-1, 620-8, 620-14, 620-20, 620-21 and 620-22. For clarity, the fitting lines are based upon the average of voltage to account for the PWM on-period and off-period. Alternatively, the fitting lines could be based on the voltage in the PWM on-period or the PWM off-period. That is, the voltage measurements may be recorded only during the PWM on-periods, with the fitting line then based upon the battery voltage during the PWM on-periods. Alternatively the voltage measurements may be recorded only during the PWM off-periods, with the fitting line then based upon the battery voltage during the PWM off-periods.

As can be seen, the gradients (or slope) of the fitted lines for aerosolisation sessions 620-21 and 620-22 are more negative than (i.e. less than) the gradients of the fitted lines for aerosolisation sessions 620-1, 620-8, 620-14 and 620-20. That is, the voltage drop of the battery 104 as a function of time for 620-21 and 620-22 is greater than that of 620-1, 620-8, 620-14 and 620-20.

Likewise, the voltage offset of the fitted lines for aerosolisation sessions for 620-21 and 620-22 is less than the voltage offset of the fitted lines for aerosolisation sessions 620-1, 620-8, 620-14 and 620-20. For clarity, the voltage offset is the point at which the fitted line meets the voltage axis at the beginning of the respective individual aerosolisation session (e.g. time=0 seconds for that specific session), not the point at which the fitted line would meet the voltage axis at 0 seconds for the entirety of the 22 aerosolisation sessions as shown in FIG. 6A).

The greater voltage drop of the battery 104 as a function of time (i.e. the more negative gradient), and the smaller voltage offset, for aerosolisation sessions for 620-21 and 620-22 is indicative of the battery 104 being in a weaker state.

In the example, the voltage drop of the battery 104 as a function of time and the voltage offset of aerosolisation session 620-22 is indicative of the battery 104 not being capable of performing any further full aerosolisation sessions. The voltage drop as a function of time, and the voltage offset, of aerosolisation session 620-21 is indicative of the battery 104 only being capable of performing one further full aerosolisation session.

Whilst FIGS. 6A to 6E show aerosolisation sessions in which a PWM power flow is utilised, the same principles as described can also be applied to a constant power flow.

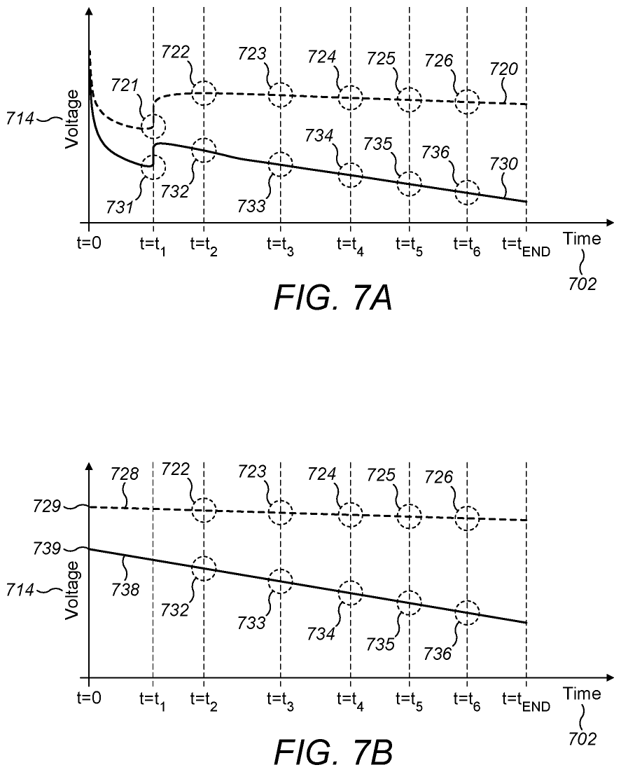

FIG. 7A shows a plot of battery voltage 714 against time (t) 702 for a ‘strong’ battery 720 and a ‘weak’ battery 730. The plots 720 and 730 can be considered to show the average battery voltage as a function for a PWM power flow to a heater 108 in an aerosolisation session. Similar plots would also be representative of the battery voltage for a constant power flow to the heater 108 in an aerosolisation session.

From t=₀ to t=t₁, the preheating phase occurs of the aerosolisation session occurs. From t=t1 to t=t_{END} (the endpoint of the aerosolisation session, where the power flow from the battery 104 to the heater 108 stops) the heating phase (of float phase) of the aerosolisation session occurs. The controller 102 can determine a plurality of battery voltage measurements during the heating phase as a function of time in the aerosolisation session. The controller 102 can then determine whether the battery 104 is capable of powering a full subsequent aerosolisation session based upon a determined relationship between these battery voltage measurements as a function of time. The controller 102 is then configured to control the aerosol generation device to perform a further action when it is determined by the controller 102 that the battery 104 is not capable of powering a full subsequent aerosolisation session. This further action can comprise the inhibiting a subsequent aerosolisation session until a predetermined requirement is met. The predetermined requirement can be charging the battery 104 for a predetermined amount of time (for example 5 minutes). When the controller 102 inhibits the subsequent aerosolisation session, the controller 102 can control the device such that if a user operates a user input (such as a button) to trigger an aerosolisation session, the session is not triggered. In some examples, this can also comprise indicating to the operator (for example by an audio, visual or haptic indicator) that the battery 104 does not have sufficient charge to power a subsequent aerosolisation session. In an example, this might be displayed on a display screen of the device. That is, an internal state of the device is indicated to the user that can instruct the user to recharge the device, rather than attempt an aerosolisation session that cannot be completed because the power source is not capable of powering the subsequent aerosolisation session.

Returning to the example of FIG. 7A, the controller 102 determines five battery voltage measurements during the heating phase at t=t₂, t=t₃, t=t₄, t=t₅ and t=t₆. For the example of the strong battery 720, the plurality of voltage measurements for t₂, t₃, t₄, t₅ and t₆ are respectively labelled 722, 723, 724, 725, and 726. For the example of the weak battery 730, the plurality of voltage measurements for t₂, t₃, t₄, t₅ and t₆ are respectively labelled 732, 733, 734, 735, and 736. Whilst five battery voltage measurements are discussed in the example of FIG. 7A, it will be understood that any suitable number of battery voltage measurements in the heating phase may instead be used for the plurality of battery voltage measurements.

The controller 102 can determine whether the power source 104 is capable of powering a full subsequent aerosolisation session based upon a linear relationship between the plurality of battery voltage measurements determined as a function of time in the heating phase. A linear fit can be applied to the battery voltage measurements, as presented for the strong battery 729 and the weak battery 739 in FIG. 7B. The linear fit provides relationship between the measured battery voltages that can defined as V=at+b, in which V is the measured battery voltage as a function of time t, a is the change in measured voltage per unit time, and b is the voltage offset.

The change in measured voltage per unit time (a) is the gradient of the linear fitting line. As can be seen in FIG. 7B, the gradient of the fitting line 739 for the weak battery is more negative (i.e. less than) the gradient of the fitting line 729 for the strong battery.

The voltage offset (b) is a voltage value determined by extrapolating the fitting line for t=0 in the aerosolisation session (i.e. the beginning time of the session). In other words, the voltage offset is the point at which the linear fitting line crosses the voltage axis when t=0. As can be seen in FIG. 7B, the voltage offset 739 for the weak battery is less than the voltage offset 729 for the strong battery.

In some examples, the controller 102 can perform the linear fitting by means of a recursive least square filter routine. Such a routine does not require computationally intensive matrix operations such as inversion, and also does not require the usage of any dedicated memory due to an avoidance of redoing the least square fit as time or the number of measurements evolves.

Other methods can also be used to obtain the parameters a and b. For example measured battery voltages at the beginning (V₁) and end (V₂) of the heating mode can be determined, with an equation such as the following being solved by the controller 102:

$${V}_{1} = {at}_{1} + b \\ {V}_{2} = {at}_{2} + b \\ {V}_{1} = {at}_{1} + {V}_{2} - {at}_{2} \\ a = ( {V}_{1} - {V}_{2} ) / ( {t}_{1} - {t}_{2} )$$

In this latter example, V₁ can comprise one or a plurality of measurements taken at the start of the heating mode, and V₂ can comprise one or a plurality of measurements taken at the end of the heating mode.

The controller 102 can determine that the power source 104 is not capable of powering a subsequent aerosolisation session when the change in measured battery voltage per unit time (i.e. a) is less than a first threshold value (i.e. when the measured battery voltage per unit time is more negative than a first threshold) and the voltage offset (i.e. b) is less than a second threshold value. These threshold values can be predetermined and stored in memory accessible by the controller 102. The controller 102 can compare the values of a and b respectively to the first threshold value and the second threshold value to determine whether the value of a is less than the first threshold value and whether the value of b is less than the second threshold value.

The controller can determine whether the next aerosolisation session can be completed even if the present aerosolisation session has not been fully finished, provided that a sufficient number battery voltage measurements have been made for the determination of a and b. For example, a sufficient number of battery voltage measurements may be 5 battery voltage measurements in the heating phase.

The aerosol generation device can further comprise a power source temperature sensor 124 configured to be used by the controller 102 to monitor the temperature of the battery 104. During the aerosolisation session, the controller 102 may determine an operating temperature of the battery 104 using the power source temperature sensor 124. When determining the first and second threshold value, the controller 102 can then determine the first threshold value and second threshold value based upon the battery temperature. The controller 102 can access a look-up table of predetermined first threshold values and predetermined second threshold values for a range of battery temperatures, in storage accessible by the controller 102, and determine which values to use based upon the measured battery 104 temperature. Alternatively, the controller 102 may use second degree polynomial functions to determine the first threshold value and the second threshold value based upon the measured battery temperature.

In some examples, only one of the change in measured battery voltage per unit time must be less than the first threshold value, or the voltage offset must be less than the second threshold value for the controller 102 to determine that a subsequent aerosolisation session cannot be performed. In some examples, both the change in measured battery voltage per unit time must be less than the first threshold value, and the voltage offset must be less than the second threshold value for the controller 102 to determine that a subsequent aerosolisation session cannot be performed. The latter example can provide a more robust determination of whether a subsequent aerosolisation session can be performed.

In the example of FIG. 7B, the first threshold value may be between the gradient of the fitting line 738 of the weak battery and the gradient of the strong battery 728. The second threshold value may be between the voltage offset 739 of the weak battery and the voltage offset 729 of the strong battery.

In this way, for the example of the weak battery, the controller 102 would determine that both the change in measured voltage per unit time (a) for the weak battery is less than the first threshold value, and the voltage offset (b) for the weak battery is less than the second threshold value; as such, the controller 102 would then determine that the battery 104 is not capable of performing a further aerosolisation session and would control the aerosol generation device to perform the further action.

For the example of the strong battery, the controller 102 would determine that both the change in measured voltage per unit time (a) for the strong battery is not less than the first threshold value, and the voltage offset (b) for the strong battery is not less than the second threshold value; as such, the controller 102 would then determine that the battery 104 is capable of performing a further aerosolisation session and would not control the aerosol generation device to perform the further action.

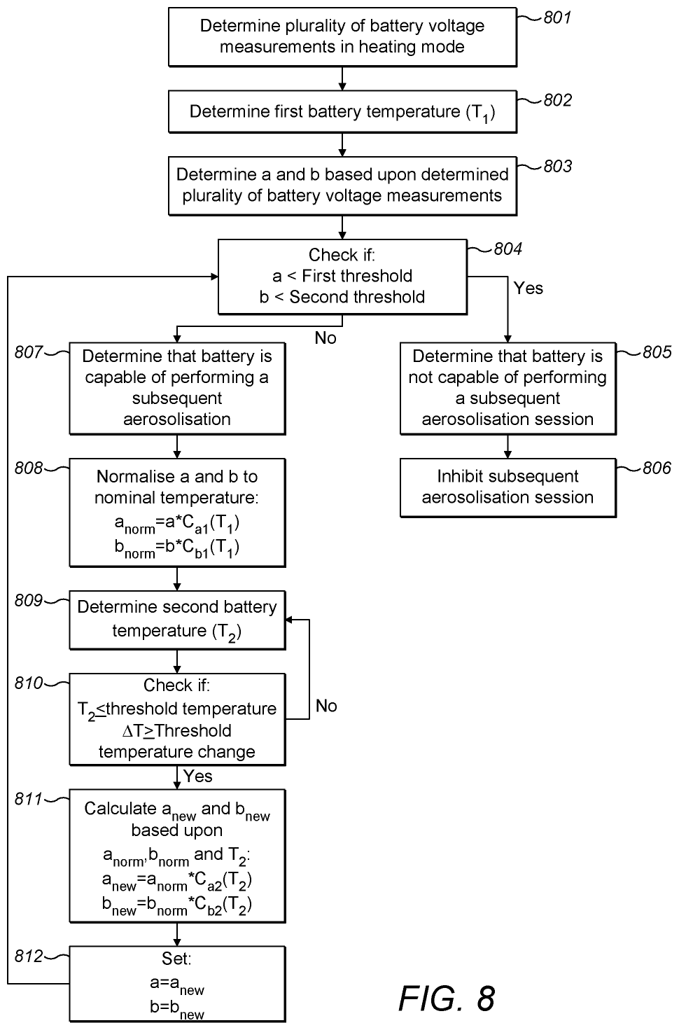

FIG. 8 presents a process flow of the operating steps performed by the controller 102 in determining whether a subsequent aerosolisation can be performed.

As already explained, at step 801 the controller 102 determines a plurality of voltage measurements of the battery 104, using the voltage sensor, during the heating mode of an aerosolisation session.

Optionally, at step 802, the controller 102 can determine the temperature of the battery 104 during the aerosolisation session using the power source temperature sensor 124. The temperature measurement of the battery 104 determined during the aerosolisation session can be considered a first temperature measurement (T₁).

At step 803, the controller 102 can determine values for a and b based upon the plurality of battery voltage measurements recorded during the heating mode, for example using a linear fitting of the plurality of voltage measurements.

At step 804, the controller 102 checks if the value of a is less than the first threshold value (check if a<First Threshold) and if the value of b is less than the second threshold value (check if b<Second Threshold), as already described.

If a is less than the first threshold and b is less than the second threshold, the controller 102 to determines that a full subsequent aerosolisation session cannot be performed (step 805). In an alternative, only one of a being less than the first threshold and b being less than the second threshold is required for the controller 102 to determine that the subsequent aerosolisation session cannot be performed (step 805).

If a is not less than the first threshold and b is not less than the second threshold, the controller 102 to determines that a full subsequent aerosolisation session can be performed (step 807). In the alternative, only one of a being not less than the first threshold and b being not less than the second threshold is required for the controller 102 to determine that the subsequent aerosolisation session can be performed (step 807).

When having determined that the full subsequent aerosolisation session cannot be performed (step 805), the process continues to step 806 at which the controller 102 performs a further action in inhibiting a subsequent aerosolisation session.

The subsequent aerosolisation session can be inhibited until a predetermined requirement is met, such as the controller 102 detecting that the battery 104 has been recharged for a predetermined amount of time. Inhibiting the subsequent aerosolisation session can involve the controller 102 controlling the aerosol generation device such that if a user operates a user input (such as a button) in an attempt to trigger an aerosolisation session, the session is not triggered. The controller 102 can also control an indicator (such as an audio, visual or haptic indicator) to indicate to the user the battery 104 does not have sufficient charge to power a subsequent aerosolisation session.

When having determined that the subsequent aerosolisation session can be performed (step 807), the controller 102 does not inhibit a subsequent aerosolisation session. In this way, no restrictions are applied to the device and the user is able to carry out a subsequent aerosolisation session after the present aerosolisation session.

In the time between the aerosolisation session in which the battery voltage measurements have been recorded to determine that a subsequent aerosolisation session can be performed, and the subsequent aerosolisation actually being performed, the aerosol generation device might be exposed to unfavourable conditions. An example might be that the aerosol generation device is exposed to cold conditions between aerosolisation sessions. Exposing the aerosol generation device to cold conditions can negatively affect the retentive capacity of the battery 104.

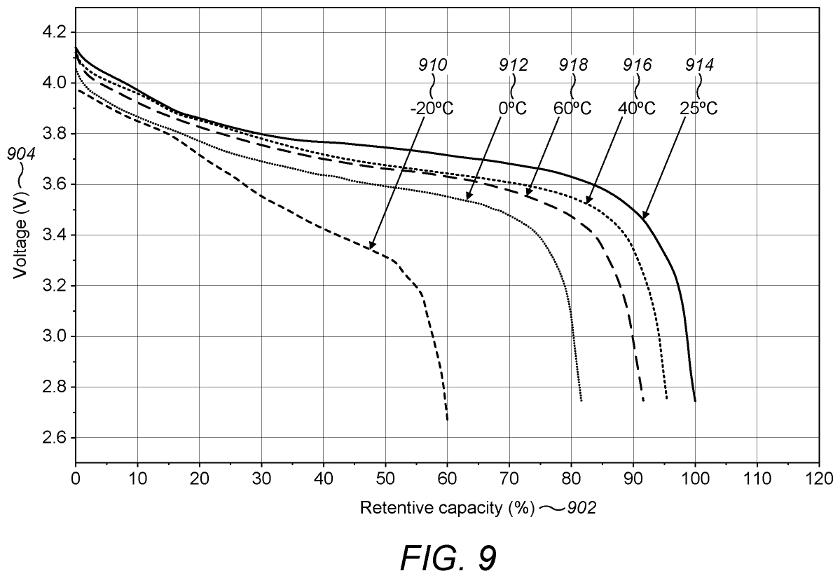

FIG. 9 shows exemplary plots of retentive capacity versus voltage for a battery discharging from 4.2 V to 2.75 V at a range of temperatures: −20° C. (plot 910), 0° C. (plot 912), 25° C. (plot 914), 40° C. (plot 916), 60° C. (plot 918). Retentive capacity can be considered as the percentage of charge stored that is actually available to be discharged from the battery 104.

As can be seen from plot 914 at 25° C., 100% of the charge stored in the battery is available to be discharged. As such, 25° C. can be considered an ideal operating temperature for the battery. Similarly, as can be respectively seen from plots 918 and 916 at 60° C. and 40° C. more than 90% of the stored charge in the battery is available to be discharged; as such, these temperatures can also be considered as temperatures at which the performance of the battery is not considerably affected.

On the other hand, as can be seen from plot 910 at −20° C. only ˜60% of the stored charge in the battery is actually available to be discharged, and as can be seen from plot 912 at 0° C. only ˜80% of the stored charge in the battery is available to be discharged. A consequence of this is that a battery 104 that is determined to have enough charge stored for a subsequent aerosolisation session, based upon battery voltage measurements recording during the previous aerosolisation session, might not actually be able to power the subsequent aerosolisation session if it is placed in a cold environment.

For example, an operator of the aerosol generation device may perform an aerosolisation session indoors in which it is determined at step 807 that the battery 104 is capable of performing a subsequent aerosolisation session. The operator may then take the device outdoors, into a cold environment (for example −20° C.) and wish to perform the subsequent aerosolisation session. However, as a much lower percentage of the stored charge is available at this low temperature (for example ˜60% in the example of FIG. 9), it may be that the battery 104 cannot actually power the subsequent aerosolisation session fully as it cannot provide all of the stored charge.

Optionally, steps 808 to 812 can take the effect of a low temperature exposure to the battery 104 between aerosolisation sessions into account in order to determine if the battery 104 can still power the subsequent aerosolisation session. In this manner, returning to step 807 of FIG. 8, when having determined that the subsequent aerosolisation session can be performed (step 807), the process can continue to step 808.

At step 808, the controller 102 can apply a normalisation to a and b to determine a normalised value for a (aₙₒᵣₘ) and a normalised value for b (bₙₒᵣₘ). These normalised or adjusted values can be determined as a function of temperature to take into account the first temperature of the battery (T₁) determined during the aerosolisation session (step 802), to normalise the values of a and b for a predetermined nominal temperature (for example 25° C.).

In an example, aₙₒᵣₘ and bₙₒᵣₘ are calculated as:

$${a}_{norm} = a \times {C}_{a 1} ( {T}_{1} ) \\ {b}_{norm} = b \times {C}_{b 1} ( {T}_{1} )$$

In this example, aₙₒᵣₘ can be calculated as the value of a multiplied by a first coefficient of a (Cₐ₁) as a function of the first temperature of the battery 104. Likewise, bₙₒᵣₘ can be calculated as the value of b multiplied by a first coefficient of b (C_{b1}) as a function of the first temperature of the battery 104.

Ranges of values of Cₐ₁ and C_{b1} as a function of temperature can, for example, be stored in look-up tables in storage accessible by the controller 102; using these look-up tables, the controller 102 can determine the values of Cₐ₁ and C_{b1} to apply to a and b based upon the determined temperature T₁. In an alternative, the values of Cₐ₁ and C_{b1} can be determined by the controller 102 using second degree polynomial functions in combination with the determined temperature T₁.

When determined, the controller 102 can save the values of aₙₒᵣₘ and bₙₒᵣₘ in storage associated with the controller 102.

At step 809, the controller 102 determines the temperature of the battery 104 at a predetermined time following the completion of the aerosolisation session, using the power source temperature sensor 124. In an example, this predetermined time may be 30 minutes. This temperature can be considered a second battery temperature (T₂). That is, the second battery temperature is the temperature of the battery 104 in a period of time after the aerosolisation session. Additionally or alternatively, determining the second battery temperature (T₂) and the subsequent steps (810 onwards) may also be carried out in response to a battery monitoring triggering condition. Such a triggering condition can be when the user specifically triggers an input configured to monitor the battery status (e.g. pressing a battery monitoring button), when a user operates a user input to activate a display on the device in which the display can include an indication of the remaining number of aerosolisation sessions that can be fully powered, or when the user attempts to trigger an aerosolisation session, or when the user activates the device in any other way.

The purpose of monitoring the second battery temperature is to determine whether the battery 104 has been exposed to a cold temperature after the aerosolisation session that may affect the ability of the battery 104 to power the subsequent aerosolisation session.

At step 810, the controller 102 determines if T₂ meets a predetermined temperature requirement. The predetermined requirement can comprise T₂ being is less than or equal to a threshold temperature (i.e. T₂≤Threshold Temperature). This threshold temperature can be a temperature at or below which there is a reasonable likelihood that the retentive capacity of the battery 104 has been decreased. In an example, the temperature threshold may be −15° C.

The predetermined temperature requirement can also comprise a change in temperature being greater than or equal to a threshold temperature change. As such, at step 810, the controller 102 also determines if the change in temperature (ΔT) is greater than or equal to a threshold temperature change (ΔT>Threshold Temperature Change). More specifically, the change in temperature can be considered a decrease in temperature, with the controller 102 determining whether the decrease is greater than or equal to a threshold decrease. In an example, the threshold temperature change may be −5° C., meaning that the controller 102 determines if the temperature decrease is ≥5° C. In another example, the threshold temperature change could be smaller than −5° C.; this can ensure higher accuracy. A larger threshold temperature change reduces the number of recalculations, providing a more efficient use of computing resources. In some examples, the threshold temperature change can vary as a function of T₂; at higher values of T₂ a larger threshold temperature change value can be used, and at lower values of T₂ a smaller threshold temperature change value can be used. This accounts for increasingly exponential changes in the battery internal resistance at lower temperatures, thereby providing a more robust determination of whether a full subsequent aerosolisation session can be performed. For example, the threshold temperature change may be −5° C. when T₂ is in the range of 10-15° C., and −2° C. when T₂ is in the range of 0-10° C.

The temperature change can be determined as the difference between T₂ and T₁.

When T₂ is not less than or equal to the threshold temperature, and the temperature change is not greater than or equal to the threshold temperature change, the controller 102 can determine that the subsequent aerosolisation session can still be performed. In this case, the controller 102 can loop back to step 809 and determine a further measurement of T₂ after a predetermined interval (for example 5 minutes). The controller 102 then repeats step 810, checking whether the new measurement of T₂ is less than or equal to the threshold temperature, and checking whether the temperature change between the new measurement of T₂ and the previous measurement of T₂ is greater than or equal to the threshold temperature change. This process repeats at predetermined intervals until either the operator triggers the subsequent aerosolisation session, or the new measurement of T₂ is less than or equal to the threshold temperature, or the temperature change between the new measurement of T₂ and the previous measurement of T₂ is greater than or equal to the threshold temperature change.

When T₂ is less than or equal to the threshold temperature, or the temperature change is greater than or equal to the threshold temperature change, the process continues to step 811 and the controller 102 can carry out a further determination as to whether the subsequent aerosolisation session can still be performed.

At step 811, the controller 102 calculates updated values of a and b based upon the second battery temperature (T₂).

The updated value of a (a_{new}) can be calculated by multiplying the stored value of aₙₒᵣₘ by a second coefficient of a (Cₐ₂) as a function of the second temperature of the battery (T₂) as:

$${a}_{new} = {a}_{norm} \times {C}_{a 2} ( {T}_{2} )$$

The updated value of b (b_{new}) can be calculated by multiplying the stored value of bₙₒᵣₘ by a second coefficient of b (C_{b2}) as a function of the second temperature of the battery 104 as:

$${b}_{new} = {b}_{norm} \times {C}_{b 2} ( {T}_{2} )$$

Ranges of values of Cₐ₂ and C_{b2} as a function of temperature can, for example, be stored in look-up tables in storage accessible by the controller 102; using these look-up tables, the controller 102 can determine the values of Cₐ₂ and C_{b2} to apply to a and b based upon the determined temperature T₂. In an alternative, the values of Cₐ₂ and C_{b2} can be determined by the controller 102 using second degree polynomial functions in combination with the determined temperature T₂.

The process then proceeds to step 812 at which the controller 102 can set the stored value of a to be equal to a_{new} (i.e. a=a_{new}) and the stored value of b to be equal to b_{new} (i.e. b=b_{new}). These updated values of a and b are then fed back into the determination performed at step 804, checking if a<First Threshold and b<Second Threshold.

The process then proceeds to step 805 when it is determined that the battery 104 is not capable of performing the subsequent aerosolisation session based upon the updated values of a and b (i.e. a_{new} and b_{new}), or step 807 when it is determined that the battery 104 is capable of performing the subsequent aerosolisation session based upon the updated values of a and b. When the process continues to step 807, steps 807 to 812 (and step 804) can continue to be looped until either it is determined that the battery 104 cannot power the subsequent aerosolisation session, or the subsequent aerosolisation session is triggered by the operator. In some examples, when the controller determines that the number of aerosolisation sessions that can be fully powered has increased or decreased, the controller can control an indicator to indicate this to the user, for example by way of a visual indicator such as a display screen in the device, an audible indicator or a haptic indicator.

In this way, the controller 102 can continue to determine whether a subsequent aerosolisation session can be performed, after the previous aerosolisation session has been completed, by monitoring the second battery temperature and updating the values of a and b determined based upon the battery voltage measurements from the previous aerosolisation session.

In the foregoing processing steps described with reference to FIG. 8, when the controller 102 determines that a subsequent aerosolisation session can be performed, the processing described with reference to FIG. 8 can be repeated in the subsequent aerosolisation session to determine whether a further aerosolisation session can be performed after the subsequent aerosolisation session, and so on.

In a further refinement to the process described with reference to FIG. 8, instead of or additionally to the determination at step 804 of the whether a<First Threshold and b<Second Threshold, the controller 102 can also performing the following determination.

The controller 102 can determine the minimum battery voltage in the preheating phase. In an example, this can be achieved by monitoring the battery voltage during the preheating phase, using the voltage sensor, recording the lowest voltage, and updating the recorded lowest voltage when a lower voltage is identified in the monitoring. Alternatively, this can be achieved by measuring the battery voltage at the endpoint of the preheating phase (t=t₁), when the battery voltage would be expected to be at its lowest.

This minimum preheating battery voltage (V_{MIN_PREHEAT}) is depicted in FIG. 7A as point 721 for the example of the ‘strong’ battery and point 731 for the example of the ‘weak’ battery.

Using the values of a and b determined at step 803, and the linear relationship V=at+b, the controller 102 can determine an expected battery voltage (V_{END}) at the end of the aerosolisation session (i.e. when t=t_{END}) through extrapolation as:

$${V}_{END} = {at}_{END} + b$$

In the example of an aerosolisation session that involves a 20 second preheating phase and a 250 second heating phase, t_{END} can be set to 270 seconds.

The controller 102 can then determine if:

$${V}_{END} < {V}_{MIN \_ PRE - HEAT} \times K ( T )$$

The extrapolated voltage at the end of the aerosolisation session (V_{END}) being less than the minimum voltage in the preheating phase (V_{MIN_PREHEAT}) multiplied by K(T) is indicative that the battery 104 is not capable of powering a full subsequent aerosolisation session. Because the preheating phase puts a greater strain on the battery 104 than the heating phase (there is some battery recovery when the preheating phase switches to the heating phase), a battery voltage that is lower at the end of the heating phase than at the end of the preheating phase is likely to be in a weak state as its voltage level will have dropped considerably in the heating phase.

On the other hand, the extrapolated voltage at the end of the aerosolisation session (V_{END}) not being less than the minimum voltage in the preheating phase (V_{MIN_PREHEAT}) multiplied by K(T) is indicative that the battery 104 is capable of powering a full subsequent aerosolisation session. This is indicative of the battery 104 being a strong state as the voltage increase due to the battery recovery when switching from the preheating phase and the heating phase is greater than the voltage drop during the heating phase.

That is, when the controller 102 determines that the extrapolated voltage at the end of the aerosolisation session (V_{END}) is less than the minimum voltage in the preheating phase (V_{MIN_PREHEAT}) multiplied by K(T), the controller 102 can determine that the battery 104 is not capable of powering a full subsequent aerosolisation session. When the controller 102 determines that the extrapolated voltage at the end of the aerosolisation session (V_{END}) is not less than the minimum voltage in the preheating phase (V_{MIN_PREHEAT}) multiplied by K(T), the controller 102 can determine that the battery 104 is capable of powering a full subsequent aerosolisation session.

This can be understood from FIG. 7A, wherein the voltage at t=t_{END} is greater than the minimum voltage in the preheating phase 721 for the plot 720 of the ‘strong’ battery, and the voltage at t=t_{END} is less than the minimum voltage in the preheating phase 731 for the plot 730 of the ‘weak’ battery.

K(T) is a constant that is a function of the battery temperature that is used as a temperature dependent scaling factor for V_{MIN_PRE-HEAT}. For example, referring to FIG. 9, it can be seen that a voltage level of 3.4 V at −20° C. does not mean that no more capacity can be discharged. However at 25° C., such a voltage is already a signal of a very much depleted battery. The constant K(T) is therefore used to improve the accuracy. In an example, V_{MIN_PRE-HEAT} might be determined 3.4 V at 25° C., 3.3 V for 0° C. and 3.25 V for −20° C. The scaling factor K(T) could therefore be 1 for higher temperatures (e.g. in the region of 25° C.) and less than 1 for lower temperatures (e.g. in the region of 0° C. to −20° C.). Preferably the scaling factor K(T) would still be >0.9 for these lower temperatures as at very low temperatures (e.g. less than −20° C.), where K(T) would be <0.9, the device will not be activated at all. The typical minimum operational temperature (that is, discharging temperature) for a typical battery in an aerosol generation device such as those of the present disclosure may be −20° C. The value of K(T) to be applied can be accessed by the controller from storage associated with the controller, based upon the determined temperature of the battery. In an example, values of K as a function of T may be stored in a look-up table; alternatively, the controller may use second degree polynomial functions to determine the value of K as a function of the measured battery temperature T.

In a simplified algorithm, K(T) may not be included and the controller can simply determine if V_{END}<V_{MIN_PRE-HEAT}, thereby reducing the computational resources expended in the calculation.

In some examples, the check of whether V_{END}<V_{MIN_PRE-HEAT}*K(T) can be performed in combination with determining whether a<First Threshold and b<Second Threshold such that three checks are performed:
(1) Check if a<First Threshold;
(2) Check if b<Second Threshold; and
(3) Check if V_{END}<V_{MIN_PRE-HEAT}*K(T)

In some examples, all three check must be true for the controller 102 to determine that the battery 104 is not capable of powering the full subsequent aerosolisation session. In other examples, only one check of the three checks must be true for the controller 102 to determine that the battery 104 is not capable of powering the subsequent aerosolisation session. In yet a further example, check (1) and (2) both need to be true, or check (3) needs to be true, for the controller 102 to determine that the battery 104 is not capable of powering the full subsequent aerosolisation session.

In other examples, the check of whether V_{END}<V_{MIN_PRE-HEAT}*K(T) can be performed as an alternative to determining whether a<First Threshold and b<Second Threshold at step 804.

Whilst the foregoing description is generally described with reference to an aerosol generation device that is configured to heat a tobacco product without burning it, the same principles can be applied to an aerosol or vapour generating device configured to aerosolise of vaporise a liquid-based aerosol or vapour generating material.

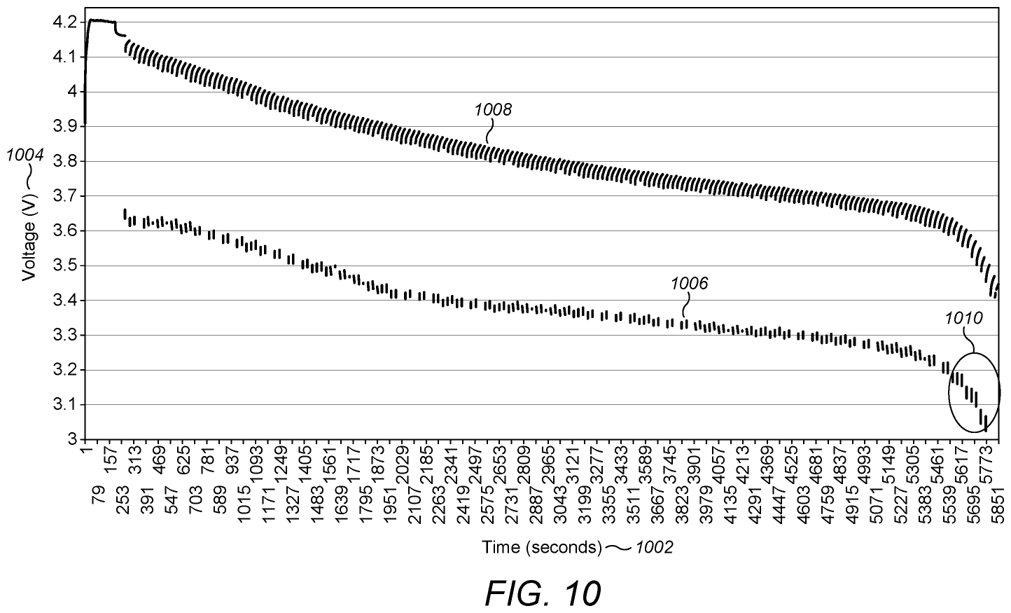

FIG. 10 shows a plot of battery voltage 1004 against time 1002 for a plurality of puffs on such a device. Line 1006 represents the battery voltage during puffs, when a heating load is applied to the battery 104 to power the heater 108. Line 1008 represents the battery voltage between puffs, as the battery 104 rests and the heating load is not being applied. As can be seen, the battery voltage generally drops as the number of puffs increases, due to the state of charge of the battery 104 decreasing when the heater 108 is powered.

When the battery 104 becomes particularly weaker, depicted by the circled area 1010, the rate at which the voltage drops as a function of time increases.

In a similar manner to steps 801 to 804, the controller 102 can record the battery voltage over a series of puffs, for example with a moving window, and continuously determine and update values of a and b. In an example, the moving window may represent the last 10 puffs. When the controller 102 determines that a is less than a first threshold, and/or b is less than a second threshold, the controller 102 determines that the battery 104 is not capable of powering a full subsequent aerosolisation session (i.e. the next puff). The controller 102 can then inhibit further/subsequent aerosolisation session(s) (i.e. puffs) until the battery 104 has been recharged, and/or control an indicator to indicate to the operator that the battery 104 is not capable of powering a subsequent aerosolisation session (i.e. the next puff) in a similar manner to steps 805 and 806.

In a similar manner to steps 804 and 807, when the controller 102 determines that a is not less than a first threshold, and/or b is not less than a second threshold, the controller 102 can determine that the battery 104 is capable of powering a full subsequent aerosolisation session (i.e. the next puff). In a similar manner to steps 808 to 812, the controller 102 can monitor the battery temperature during the period of time between the previous puff and the subsequent puff to determine whether the battery 104 can power the subsequent puff based upon the battery temperature.

In other words, in some examples both a<First Threshold and b<Second Threshold must be true for the controller to determine that the battery 104 is capable of powering a full subsequent aerosolisation session (i.e. the next puff). In other examples, only of a<First Threshold and b<Second Threshold must be true for the controller to determine that the battery 104 is capable of powering a full subsequent aerosolisation session (i.e. the next puff). The former of these examples provides a more robust determination of whether the battery 104 is capable of powering a full subsequent aerosolisation session (i.e. the next puff).

Whilst the foregoing description generally refers to the power source 104 as a battery, the principles that are described can also be applied to an aerosol generation device having an alternative power source, such as a plurality of batteries, one or more hybrid capacitors, one or more supercapacitors, or a combination thereof.

In the preceding description, the controller 102 can store instructions for controlling the aerosol generation device and power system in the described manners. The skilled person will readily understand that the controller 102 can be configured to execute any of the aforementioned manners in combination with one another as appropriate. The processing steps described herein carried out by the controller 102 may be stored in a non-transitory computer-readable medium, or storage, associated with the controller 102. A computer-readable medium can include non-volatile media and volatile media. Volatile media can include semiconductor memories and dynamic memories, amongst others. Non-volatile media can include optical disks and magnetic disks, amongst others.

It will be readily understood to the skilled person that the preceding embodiments in the foregoing description are not limiting; features of each embodiment may be incorporated into the other embodiments as appropriate.

1. An aerosol generation device configured to aerosolise an aerosol generating consumable in an aerosolisation session, the aerosol generation device comprising:
a power source;
a controller configured to control a power flow from the power source to a heater in the aerosolisation session, determine a plurality of power source measurements of the power source as a function of time during the aerosolisation session, and determine whether the power source is capable of powering a subsequent aerosolisation session based upon a determined relationship between the power source measurements as a function of time;
wherein the controller is configured to control the aerosol generation device to perform a further action when it is determined by the controller that the power source is not capable of powering a subsequent aerosolisation session.

2. The aerosol generation device of claim 1, wherein the aerosolisation session comprises a heating phase in which the heater is maintained at the aerosolisation temperature, and the plurality of power source measurements as a function of time comprise a plurality of power source measurements determined in the heating phase.

3. The aerosol generation device of claim 1, wherein the controller is configured to determine whether the power source is capable of powering a subsequent aerosolisation session based upon a linear relationship between the power source measurements as a function of time; and
wherein the power source measurements are voltage measurements of the power source, and the linear relationship is defined as V=at+b, in which V is measured power source voltage as a function of time t in the aerosolisation session, a is change in measured power source voltage per unit time, and b is a voltage offset.

4. The aerosol generation device of claim 3, wherein the controller is further configured to determine that the power source is not capable of powering a subsequent aerosolisation session when the change in measured power source voltage per unit time is less than a first threshold and the voltage offset is less than a second threshold.

5. The aerosol generation device of claim 4, further comprising a temperature sensor configured to determine a first temperature of the power source; and
wherein the controller is configured to determine the first threshold and the second threshold as a function of the determined first temperature of the power source.

6. The aerosol generation device of claim 5, wherein the controller is configured to normalise the change in measured power source voltage per unit time and voltage offset to a nominal temperature based upon the determined first temperature of the power source.

7. The aerosol generation device of claim 6, wherein the controller is configured to:
determine a second temperature of the power source after the aerosolisation session; and
when the second temperature meets a predetermined temperature requirement, recalculate the normalised change in power source voltage per unit time and the normalised voltage offset based upon the second temperature.

8. The aerosol generation device of claim 7, wherein the predetermined temperature requirement comprises the second temperature being less than a threshold temperature, and/or a temperature change between the first temperature and a second temperature exceeding a threshold temperature change.

9. The aerosol generation device of claim 7, wherein the controller is configured to determine that the power source is not capable of powering the subsequent aerosolisation session when the recalculated normalised change in voltage per unit time is less than the first threshold and the recalculated normalised voltage offset is less than the second threshold.

10. The aerosol generation device of claim 1, wherein the aerosolisation session comprises a preheating phase in which the heater is heated to a predetermined aerosolisation temperature; and
wherein the controller is configured to:
determine a minimum voltage measurement of the power source in the preheating phase;
determine a voltage of the power source at an endpoint of the aerosolisation session based upon the linear relationship; and
determine whether the power source is capable of powering a subsequent aerosolisation session based upon a comparison between the determined voltage at the endpoint of the aerosolisation session and the minimum voltage measurement in the preheating phase.

11. The aerosol generation device of claim 1, wherein the further action comprises inhibiting a subsequent aerosolisation session until a predetermined requirement is met.

12. The aerosol generation device of claim 11, wherein the predetermined requirement comprises charging the power source for a predetermined amount of time.

13. The aerosol generation device of claim 1, wherein the aerosol generation device further comprises an indicator, and the further action comprises indicating, by the indicator, when it is determined by the controller that the power source is not capable of powering a subsequent aerosolisation session.

14. A method of operating an aerosol generation device configured to aerosolise an aerosol generating consumable in an aerosolisation session, the method comprising:
controlling a power flow from a power source to a heater in the aerosolisation session;
determining a plurality of power source measurements of the power source as a function of time during the aerosolisation session;
determining whether the power source is capable of powering a subsequent aerosolisation session based upon a determined relationship between the power source measurements as a function of time; and
performing a further action when it is determined that the power source is not capable of powering a subsequent aerosolisation session.

15. A non-transitory computer-readable medium storing instructions that, when executed by one or more processors of a controller configured for operation with an aerosol generation device configured to aerosolise an aerosol generating consumable in an aerosolisation session, cause the one or more processors to perform steps comprising:
controlling a power flow from a power source to a heater in the aerosolisation session;
determining a plurality of power source measurements of the power source as a function of time during the aerosolisation session;
determining whether the power source is capable of powering a subsequent aerosolisation session based upon a determined relationship between the power source measurements as a function of time; and
performing a further action when it is determined that the power source is not capable of powering a subsequent aerosolisation session.
